(19) United States
(12) Patent Application Publication
(10) Pub. No.: US 2015/0327371 A1
(43) Pub. Date: Nov. 12, 2015

(54) METHOD OF MAKING A FLEXIBLE MULTILAYER CIRCUIT BOARD

(71) Applicant: MICROCOSM TECHNOLOGY CO., LTD., Tainan City (TW)

(72) Inventors: Tang-Chieh HUANG, Tainan City (TW); Chau-Chin CHUANG, Kaohsiung City (TW)

(21) Appl. No.: 14/684,831

(22) Filed: Apr. 13, 2015

(30) Foreign Application Priority Data
May 9, 2014 (TW) 103116596

(51) Int. Cl. H05K 3/00; H05K 3/46

(52) U.S. Cl. CPC H05K 3/0091; H05K 3/0035; H05K 3/46

(57) ABSTRACT

A method of making a multilayer circuit board includes: forming and exposing a first polyimide photoresist layer; forming holes in the first polyimide photoresist layer; forming a second metal layer on the first polyimide photoresist layer; forming a first photoresist mask layer on the second metal layer; patterning the first photoresist mask layer and the second metal layer; forming a second polyimide photoresist layer on the patterned second metal layer; exposing the second polyimide photoresist layer; forming a hole in the second polyimide photoresist layer; forming a third metal layer on the second polyimide photoresist layer; and forming and patterning a second photoresist mask layer on the third metal layer.

### CROSS-REFERENCE TO RELATED APPLICATION

This application claims priority of Taiwanese Patent Application No. 103116596, filed on May 9, 2014, the entire disclosure of which is hereby incorporated by reference.

### FIELD

The disclosure relates to a method of making a flexible multilayer circuit board, more particularly to a method of making a flexible multilayer circuit board that includes forming a plurality of polyimide photoresist layers.

### BACKGROUND

U.S. Patent Application Publication No. 2014/0224527 discloses a conventional method of making a flexible multilayer circuit board. The conventional method includes the steps of: providing a substrate; forming a polyamic acid layer on the substrate and conducting a first pre-curing process on the polyamic acid layer, such that the polyamic acid is semi-cured; coating a photoresist on the polyamic acid layer and conducting a second pre-curing process on the photoresist and the polyamic acid; exposing and developing the photoresist to partially remove the photoresist and the polyamic acid layer thereunder; forming an enhancing layer; forming a first electrically conducting layer on the enhancing layer; removing the remaining photoresist and revealing the polyamic acid layer thereunder; curing the remaining polyamic acid to form a precursor substrate of polyimide; coating a second electrically conducting layer on the precursor substrate and selectively forming an electric circuit with the first electrically conducting layer; and forming an electrically insulating layer on the precursor substrate to cover the electric circuit.

It is known in the art that polyamic acid is a precursor of polyimide and can be converted into polyimide by undergoing a dehydration and ring-close reaction under a temperature around 300° C. to 350° C. Hence, using polyamic acid to form the precursor substrate of polyimide according to the aforesaid conventional method tends to damage the electric circuit formed thereon and the connection between the electric circuit and the precursor substrate. In addition, the aforesaid conventional method requires application of polyamic acid and the photoresist and removal of the remaining photoresist before curing or baking the remaining polyamic acid to form the precursor substrate, which renders the aforesaid conventional method complicate.

### SUMMARY

Therefore, an object of the disclosure is to provide a method of making a flexible multilayer circuit board that can overcome at least one of the aforesaid drawbacks of the prior art.

According to one aspect of the disclosure, there is provided a method of making a flexible multilayer circuit board. The method includes: preparing an assembly of a flexible substrate and a first metal layer that is formed on a first surface of the flexible substrate, the first metal layer being patterned and having a plurality of first conductive traces; forming a first polyimide photoresist layer on the first metal layer and areas of the first surface that are exposed from the first metal layer; exposing the first polyimide photoresist layer to a light to permit the first polyimide photoresist layer to undergo crosslinking reaction; forming a plurality of holes in the crosslinked first polyimide photoresist layer, such that each of the holes exposes an area of a corresponding one of the first conductive traces; forming a second metal layer on the crosslinked first polyimide photoresist layer, such that the second metal layer extends into the holes in the crosslinked first polyimide photoresist layer to contact the first conductive traces that are exposed from the holes; forming a first photoresist mask layer on the second metal layer; patterning the first photoresist mask layer and the second metal layer using photolithography techniques so as to form a plurality of second conductive traces on the crosslinked first polyimide photoresist layer; removing the patterned first photoresist mask layer from the second conductive traces; forming a second polyimide photoresist layer on the second conductive traces and areas of the crosslinked first polyimide photoresist layer that are exposed from the second conductive traces; exposing the second polyimide photoresist layer to a light to permit the second polyimide photoresist layer to undergo crosslinking reaction; forming at least one hole in the crosslinked second polyimide photoresist layer, such that the hole in the crosslinked second polyimide photoresist layer exposes an area of a corresponding one of the second conductive traces; forming a third metal layer on the crosslinked second polyimide photoresist layer, such that the third metal layer extends into the hole in the crosslinked second polyimide photoresist layer to contact a corresponding one of the second conductive traces; forming a second photoresist mask layer on the third metal layer; patterning the second photoresist mask layer and the third metal layer using photolithography techniques so as to form a plurality of third conductive traces on the crosslinked second polyimide photoresist layer; removing the patterned second photoresist mask layer from the third conductive traces; and forming a third polyimide photoresist layer on the third conductive traces and areas of the crosslinked second polyimide photoresist layer that are exposed from the third conductive traces.

According to another aspect of the disclosure, there is provided a method of making a flexible multilayer circuit board. The method includes: preparing an assembly of a flexible substrate and a first metal layer that is formed on a first surface of the flexible substrate, the first metal layer being patterned and having a plurality of first conductive traces; forming a first polyimide photoresist layer on the first metal layer and areas of the first surface that are exposed from the first metal layer; exposing the first polyimide photoresist layer to a light to permit the first polyimide photoresist layer to undergo crosslinking reaction; forming a second metal layer on the crosslinked first polyimide photoresist layer; forming a first photoresist mask layer of a polyimide photoresist on the second metal layer; patterning the first photoresist mask layer and the second metal layer using photolithography techniques so as to form a plurality of second conductive traces on the crosslinked first polyimide photoresist layer and a plurality of pattern holes extending through the patterned second metal layer and the patterned first photoresist mask layer; filling the pattern holes with a polyimide photoresist and exposing the polyimide photoresist in the pattern holes to a light to permit the polyimide photoresist in the pattern holes to undergo crosslinking reaction, so that the crosslinked polyimide photoresist in the pattern holes and the patterned first photoresist mask layer cooperatively define a second polyimide photoresist layer; and forming at least one hole in the second polyimide photoresist layer, such that the at least one hole exposes an area of a corresponding one of the second conductive traces.

### BRIEF DESCRIPTION OF THE DRAWINGS

Other features and advantages of the disclosure will become apparent in the following detailed description of the embodiments, with reference to the accompanying drawings, of which:

FIGS. 1 to 16 are schematic views to illustrate consecutive steps of the first embodiment of a method of making a flexible multilayer circuit board according to the disclosure;

FIG. 17 is a schematic view to illustrate an embodiment of a flexible multilayer circuit board according to the disclosure; and

FIGS. 18 to 28 are schematic views to illustrate consecutive steps of the second embodiment of the method of making a flexible multilayer circuit board according to the disclosure.

### DETAILED DESCRIPTION

Before the disclosure is described in greater detail, it should be noted that like elements are denoted by the same reference numerals throughout the disclosure.

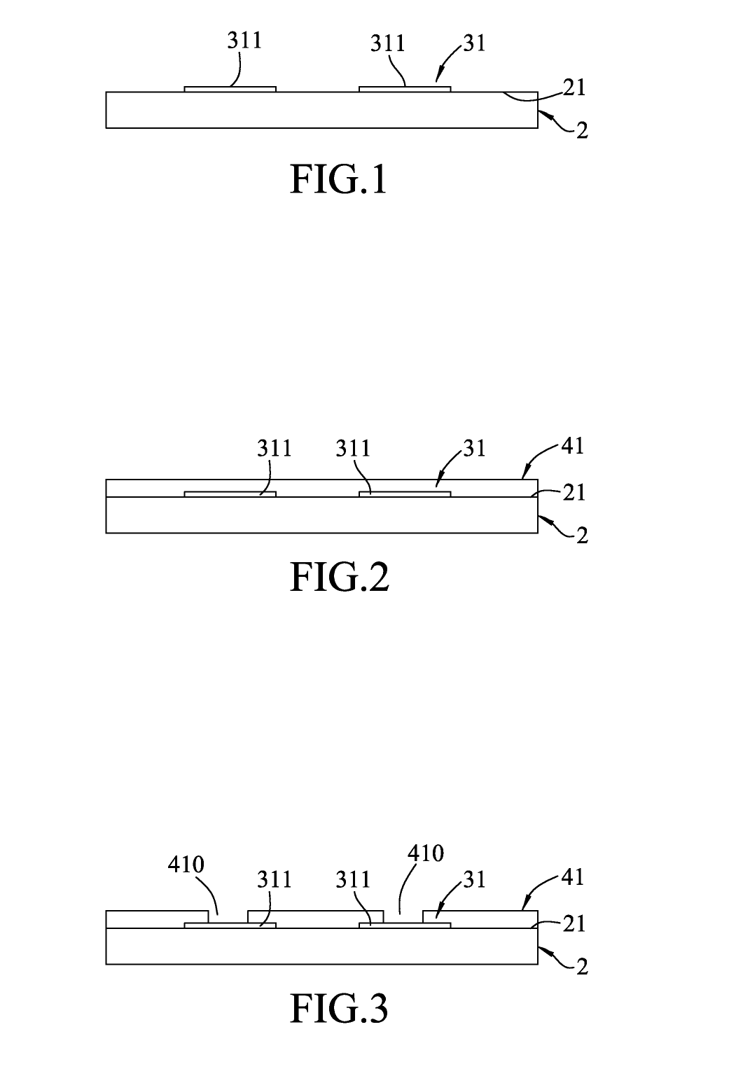

FIGS. 1 to 16 illustrate consecutive steps of the first embodiment of a method of making a flexible multilayer circuit board according to the present invention.

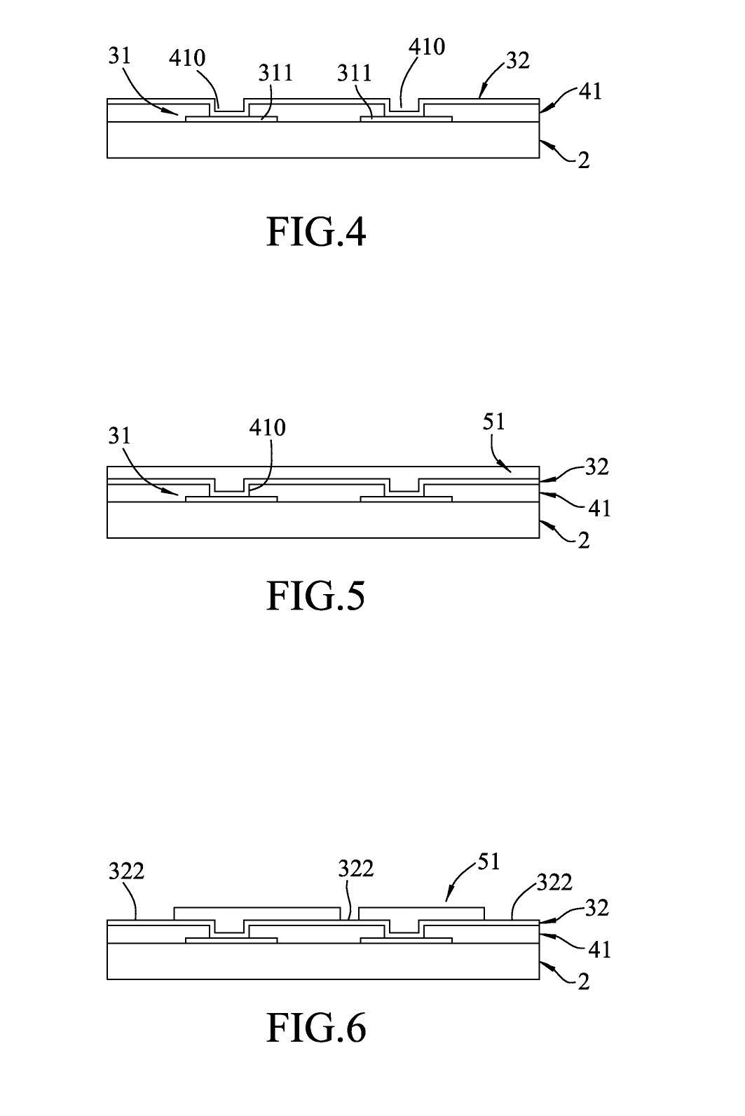

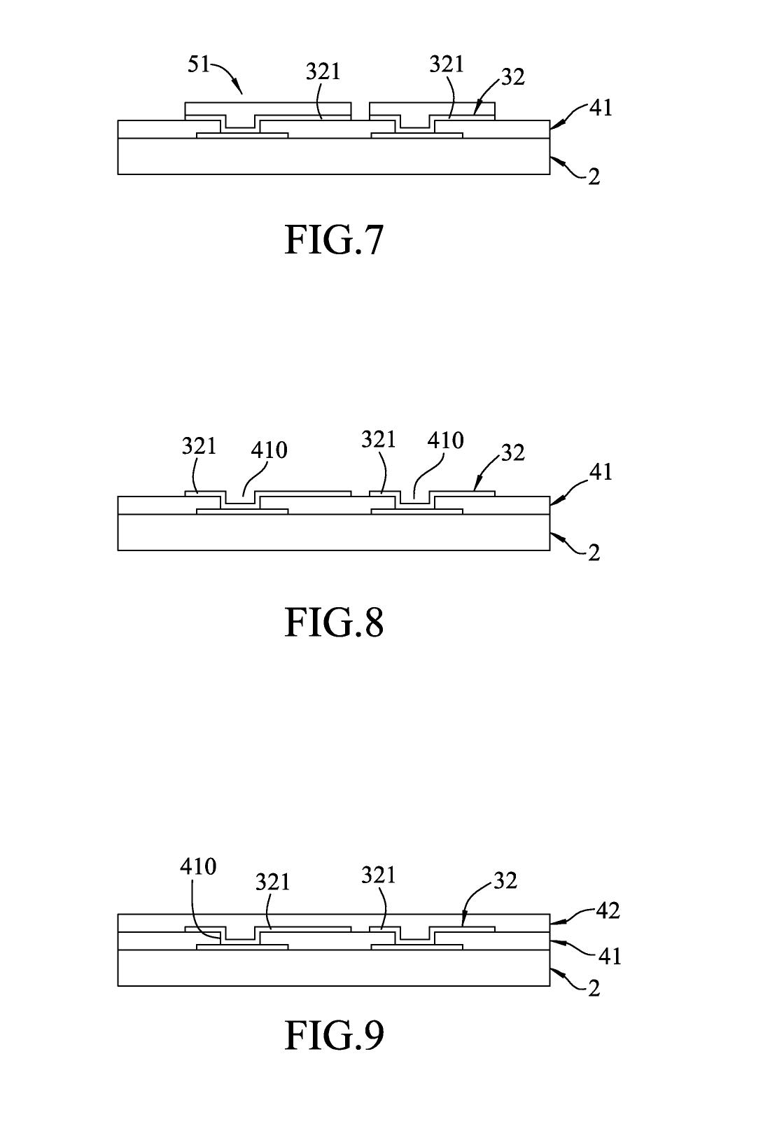

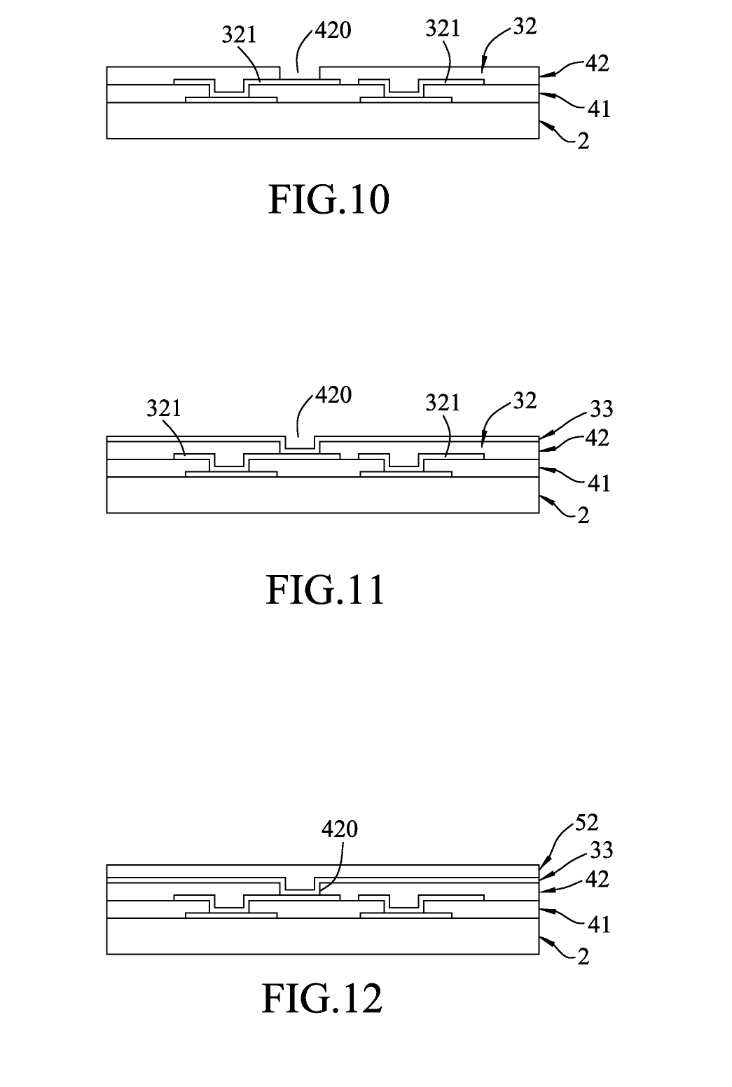

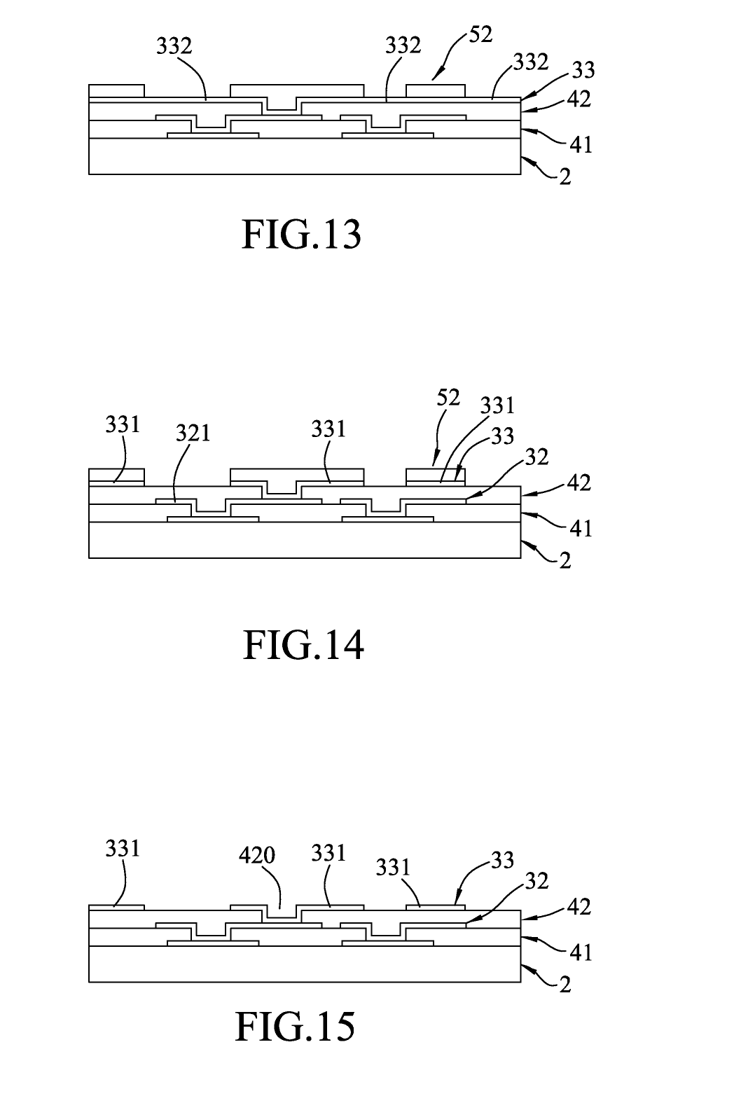

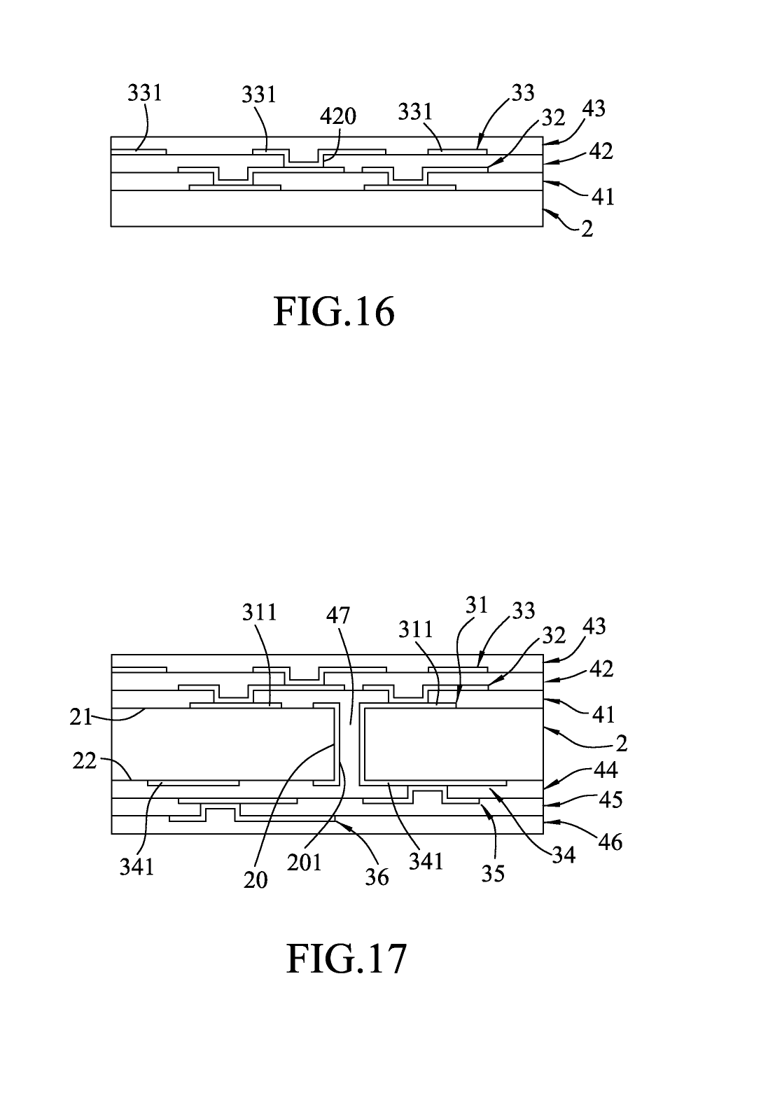

The method includes: (a) preparing an assembly of a flexible substrate 2 and a first metal layer 31 that is formed on a first surface 21 of the flexible substrate 2, the first metal layer 31 being patterned and having a plurality of first conductive traces 311 (see FIG. 1); (b) forming a first polyimide photoresist layer 41 on the first metal layer 31 and areas of the first surface 21 that are exposed from the first metal layer 31 (see FIG. 2); (c) exposing the first polyimide photoresist layer 41 to a light (not shown) to permit the first polyimide photoresist layer 41 to undergo crosslinking reaction; (d) forming a plurality of holes 410 in the crosslinked first polyimide photoresist layer 41, such that each of the holes 410 exposes an area of a corresponding one of the first conductive traces 311 (see FIG. 3), the holes 410 being formed by dry etching or laser drilling; (e) forming a second metal layer 32 on the crosslinked first polyimide photoresist layer 41, such that the second metal layer 32 extends into the holes 410 in the crosslinked first polyimide photoresist layer 41 to contact the first conductive traces 311 that are exposed from the holes 410 (see FIG. 4); (f) forming a first photoresist mask layer 51 on the second metal layer 32 (see FIG. 5); (g) patterning the first photoresist mask layer 51 and the second metal layer 32 using photolithography techniques so as to form a plurality of second conductive traces 321 (see FIG. 7) on the crosslinked first polyimide photoresist layer 41, the first photoresist mask layer 51 undergoing soft baking, exposure and development in the photolithography process, so that the first photoresist mask layer 51 is patterned according to a predetermined pattern to expose areas 322 of the second metal layer 32 to be etched (see FIG. 6), the exposed areas 322 of the second metal layer 32 being removed by etching in the photolithography process so as to form the second conductive traces 321; (h) removing the patterned first photoresist mask layer 51 from the second conductive traces 321 (see FIGS. 7 and 8); (i) forming a second polyimide photoresist layer 42 on the second conductive traces 321 and areas of the crosslinked first polyimide photoresist layer 41 that are exposed from the second conductive traces 321 (see FIG. 9); (j) exposing the second polyimide photoresist layer 42 to a light (not shown) to permit the second polyimide photoresist layer 42 to undergo crosslinking reaction; (k) forming at least one hole 420 in the crosslinked second polyimide photoresist layer 42, such that the hole 420 in the crosslinked second polyimide photoresist layer 42 exposes an area of a corresponding one of the second conductive traces 321 (see FIG. 10), the at least one hole 420 being formed by dry etching or laser drilling; (l) forming a third metal layer 33 on the crosslinked second polyimide photoresist layer 42, such that the third metal layer 33 extends into the hole 420 in the crosslinked second polyimide photoresist layer 42 to contact the corresponding one of the second conductive traces 321 (see FIG. 11); (m) forming a second photoresist mask layer 52 on the third metal layer 33 (see FIG. 12); (n) patterning the second photoresist mask layer 52 and the third metal layer 33 using photolithography techniques so as to form a plurality of third conductive traces 331 on the crosslinked second polyimide photoresist layer 42 (see FIG. 14), the second photoresist mask layer 52 undergoing soft baking, exposure and development in the photolithography process, so that the second photoresist mask layer 52 is patterned according to a predetermined pattern to expose areas 332 of the third metal layer 33 to be etched (see FIG. 13), the exposed areas 332 of the third metal layer 33 being removed by etching in the photolithography process so as to form the third conductive traces 331; (o) removing the patterned second photoresist mask layer 52 from the third conductive traces (see FIGS. 14 and 15); (p) forming a third polyimide photoresist layer 43 on the third conductive traces 331 and areas of the crosslinked second polyimide photoresist layer 42 that are exposed from the third conductive traces 331 (see FIG. 16); and (q) exposing the third polyimide photoresist layer 43 to a light (not shown) to permit the third polyimide photoresist layer 43 to undergo crosslinking reaction.

In this embodiment, the flexible substrate 2 is made of polyimide.

Preferably, the first and second photoresist mask layers 51, 52 are made of a polyimide photoresist.

The first metal layer 31 may be a metal foil laminated to the flexible substrate 2. Formation of the second and third metal layers 32, 33 may be conducted using physical vapor deposition techniques.

Formation of the first, second and third polyimide photoresist layers 41, 42, 43 may be conducted using coating or printing techniques. Each of the crosslinked first, second and third polyimide photoresist layers 41, 42, 43 may have a layer thickness ranging from 25 μm to 50 μm.

FIG. 17 illustrates one modified embodiment of the flexible multilayer circuit board according to the present invention. The modified embodiment differs from the flexible multilayer circuit board of FIG. 16 in that the modified embodiment further includes a fourth polyimide photoresist layer 44, a fifth polyimide photoresist layer 45, a sixth polyimide photoresist layer 46, a patterned fourth metal layer 34, a patterned fifth metal layer 35, and a patterned sixth metal layer 36, which are formed on a second surface 22 (opposite to the first surface 21) of the flexible substrate 2 in similar manners as those of the first polyimide photoresist layer 41, the second polyimide photoresist layer 42, the third polyimide photoresist layer 43, the patterned first metal layer 31, the patterned second metal layer 32, and the patterned third metal layer 33. In addition, the flexible substrate 2 is formed with at least one through-hole 20. The fourth metal layer 34 includes a plurality of fourth conductive traces 341 formed on the second surface 22 of the flexible substrate 2. A conductor layer 201 is formed on a hole-defining wall of the through-hole 20, and interconnects a corresponding one of the first conductive traces 311 and a corresponding one of the fourth conductive traces 341. A polyimide photoresist pillar 47 together with the conductor layer 201 fills the through-hole 20, and is disposed between and interbonded to the first and fourth polyimide photoresist layers 41, 44.

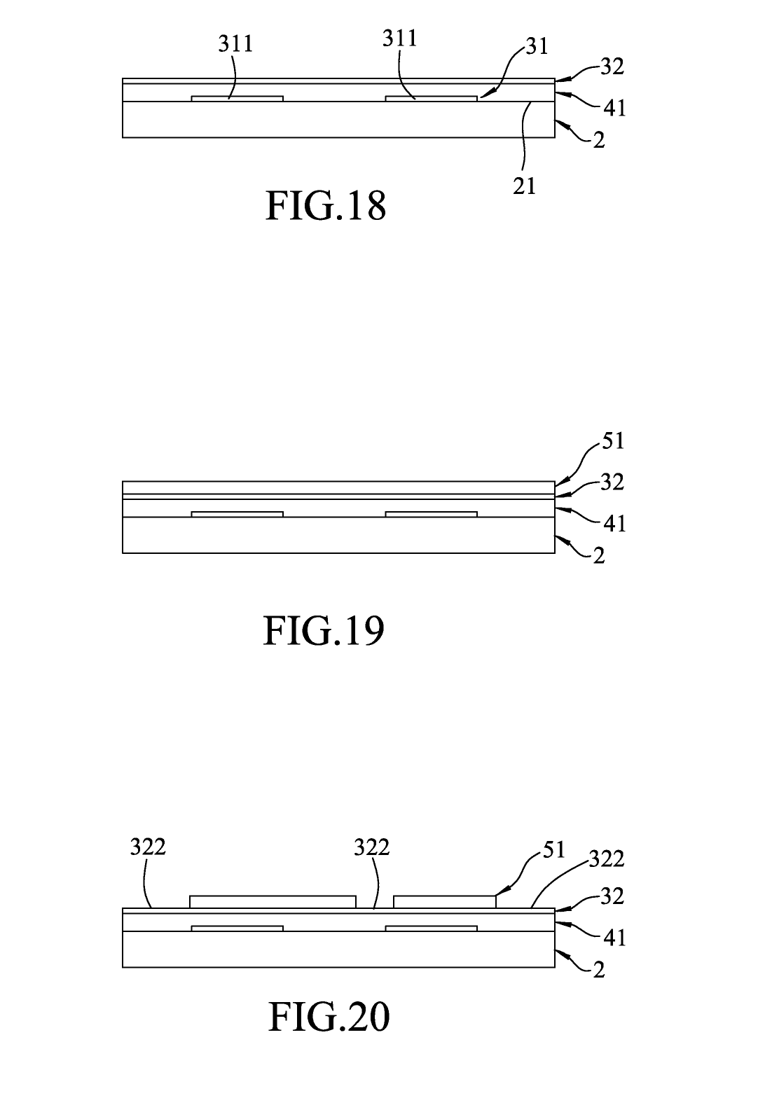

FIGS. 18 to 28 illustrate consecutive steps of the second embodiment of the method of making a flexible multilayer circuit board according to the present invention.

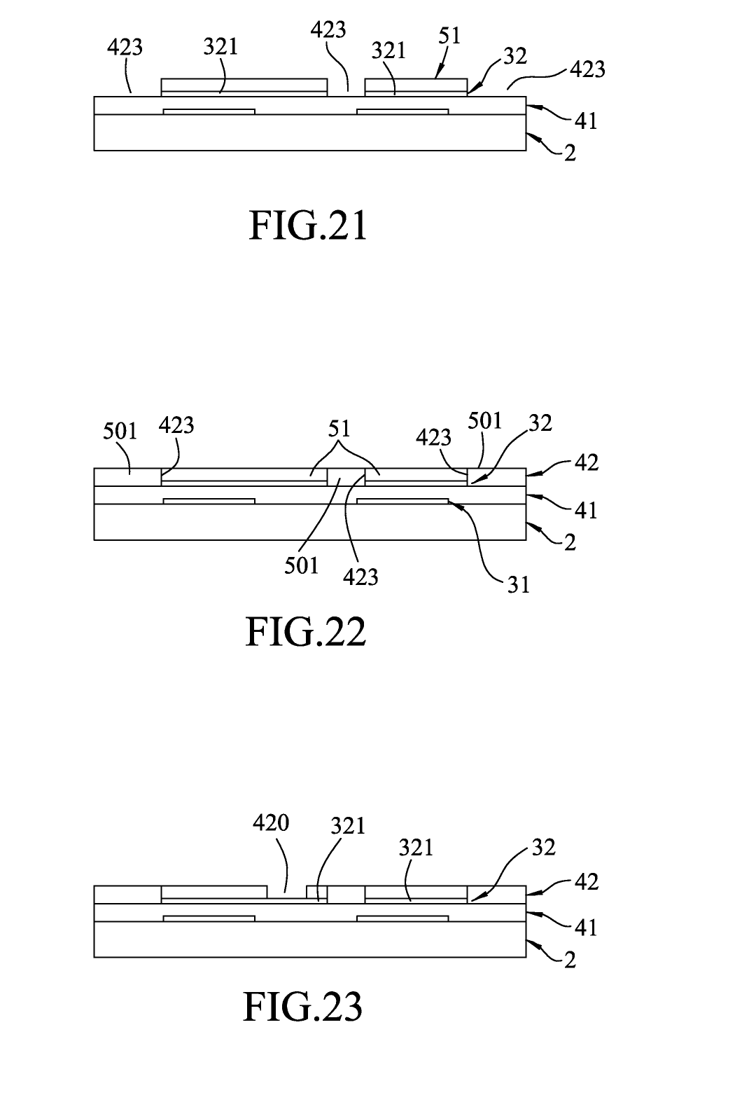

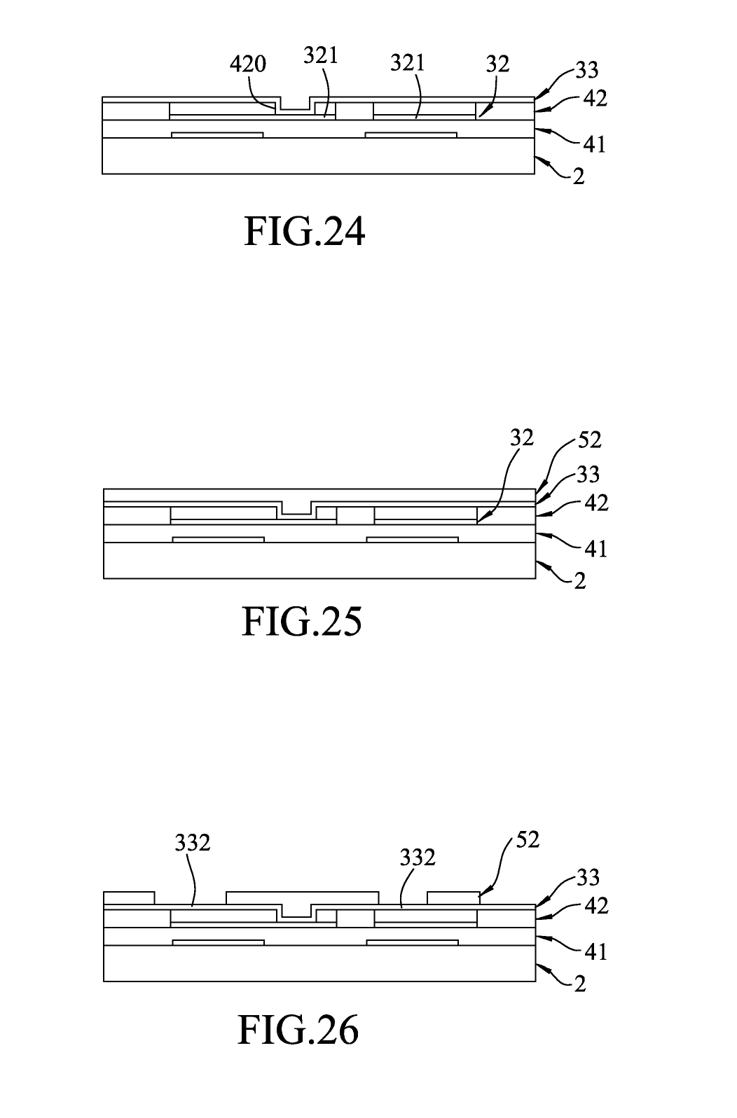

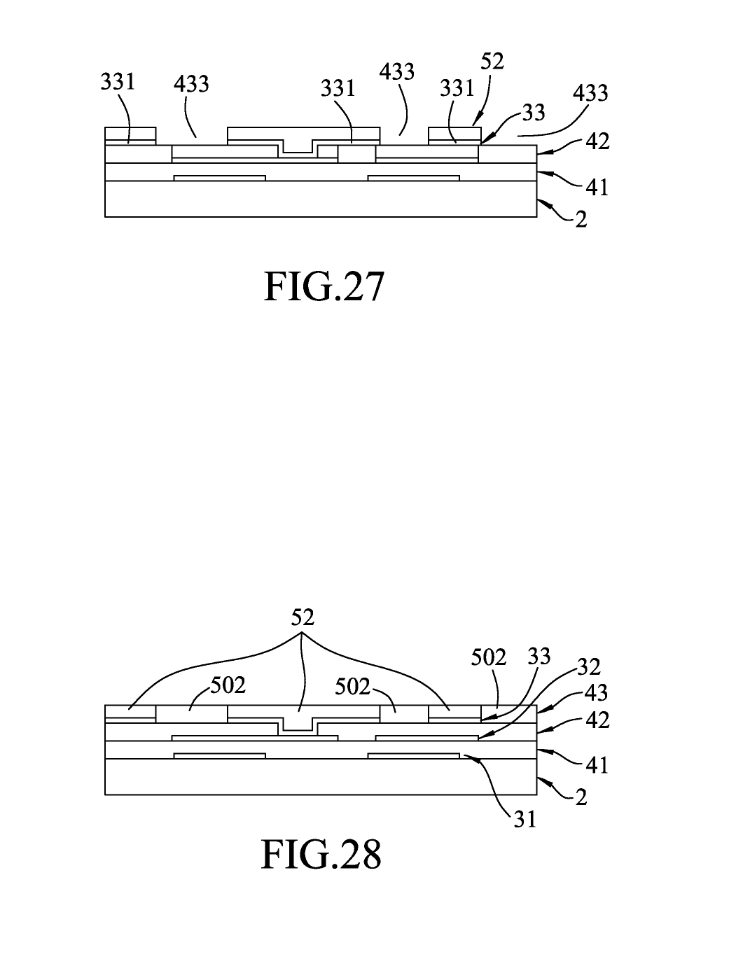

In this embodiment, the method includes the steps of: (A) preparing an assembly of a flexible substrate 2 and a first metal layer 31 that is formed on a first surface 21 of the flexible substrate 2, the first metal layer 31 being patterned and having a plurality of first conductive traces 311 (same as the aforesaid step (a) shown in FIG. 1); (B) forming a first polyimide photoresist layer 41 on the first metal layer 31 and areas of the first surface 21 that are exposed from the first metal layer 31 (same as the aforesaid step (b) shown in FIG. 2); (C) exposing the first polyimide photoresist layer 41 to a light (not shown) to permit the first polyimide photoresist layer 41 to undergo crosslinking reaction (same as the aforesaid step (c)); (D) forming a second metal layer 32 on the crosslinked first polyimide photoresist layer 41 (see FIG. 18); (E) forming a first photoresist mask layer 51 of a polyimide photoresist on the second metal layer 32 (see FIG. 19); (F) patterning the first photoresist mask layer 51 and the second metal layer 32 using photolithography techniques so as to form a plurality of second conductive traces 321 on the crosslinked first polyimide photoresist layer 41 and a plurality of pattern holes 423 extending through the patterned second metal layer 32 and the patterned first photoresist mask layer 51 (see FIG. 21), the first photoresist mask layer 51 undergoing soft baking, exposure, and development in the photolithography process, so that the first photoresist mask layer 51 is patterned according to a predetermined pattern to expose areas 322 of the second metal layer 32 to be etched (see FIG. 20), the exposed areas 322 of the second metal layer 32 being removed by etching in the photolithography process so as to form the second conductive traces 321 and the pattern holes 423; (G) filling the pattern holes 423 with a first polyimide photoresist 501 and exposing the first polyimide photoresist 501 in the pattern holes 423 to a light (not shown) to permit the first polyimide photoresist 501 in the pattern holes 423 to undergo crosslinking reaction, so that the crosslinked first polyimide photoresist 501 in the pattern holes 423 and the patterned first photoresist mask layer 51 cooperatively define a second polyimide photoresist layer 42 (see FIG. 22); (H) forming at least one hole 420 in the second polyimide photoresist layer 42, such that the at least one hole 420 exposes an area of a corresponding one of the second conductive traces 321 (see FIG. 23); (I) forming a third metal layer 33 on the second polyimide photoresist layer 42, such that the third metal layer 33 extends into the at least one hole 420 in the second polyimide photoresist layer 42 to contact a corresponding one of the second conductive traces 321 (see FIG. 24); (J) forming a second photoresist mask layer 52 of a polyimide photoresist on the third metal layer 33 (see FIG. 25); (K) patterning the second photoresist mask layer 52 and the third metal layer 33 using photolithography techniques so as to form a plurality of third conductive traces 331 on the second polyimide photoresist layer 42 and a plurality of pattern holes 433 extending through the patterned third metal layer 33 and the patterned second photoresist mask layer 52 (see FIG. 27), the second photoresist mask layer 52 undergoing soft baking, exposure, and development in the photolithography process, so that the second photoresist mask layer 52 is patterned according to a predetermined pattern to expose areas 332 of the third metal layer 33 to be etched (see FIG. 26), the exposed areas 332 of the third metal layer 33 being removed by etching in the photolithography process so as to form the third conductive traces 331 and the pattern holes 433; and (L) filling the pattern holes 433 with a second polyimide photoresist 502 and exposing the second polyimide photoresist 502 in the pattern holes 433 to a light (not shown) to permit the second polyimide photoresist 502 in the pattern holes 433 to undergo crosslinking reaction, so that the crosslinked second polyimide photoresist 502 in the pattern holes 433 and the patterned second photoresist mask layer 52 cooperatively define a third polyimide photoresist layer 43 (see FIG. 28).

By using the polyimide photoresist to form the first and second polyimide photoresist layers 41, 42 for the laying of the patterned second and third metal layers 32, 33 thereon in the method of the present invention, the aforesaid drawbacks associated with the prior art can be alleviated.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation and equivalent arrangements.

What is claimed is:

1. A method of making a flexible multilayer circuit board, comprising:
preparing an assembly of a flexible substrate and a first metal layer that is formed on a first surface of the flexible substrate, the first metal layer being patterned and having a plurality of first conductive traces;
forming a first polyimide photoresist layer on the first metal layer and areas of the first surface that are exposed from the first metal layer;
exposing the first polyimide photoresist layer to a light to permit the first polyimide photoresist layer to undergo crosslinking reaction;
forming a plurality of holes in the crosslinked first polyimide photoresist layer, such that each of the holes exposes an area of a corresponding one of the first conductive traces;
forming a second metal layer on the crosslinked first polyimide photoresist layer, such that the second metal layer extends into the holes in the crosslinked first polyimide photoresist layer to contact the first conductive traces that are exposed from the holes;
forming a first photoresist mask layer on the second metal layer;
patterning the first photoresist mask layer and the second metal layer using photolithography techniques so as to form a plurality of second conductive traces on the crosslinked first polyimide photoresist layer;
removing the patterned first photoresist mask layer from the second conductive traces;
forming a second polyimide photoresist layer on the second conductive traces and areas of the crosslinked first polyimide photoresist layer that are exposed from the second conductive traces;
exposing the second polyimide photoresist layer to a light to permit the second polyimide photoresist layer to undergo crosslinking reaction;
forming at least one hole in the crosslinked second polyimide photoresist layer, such that the hole in crosslinked second polyimide photoresist layer exposes an area of a corresponding one of the second conductive traces;
forming a third metal layer on the crosslinked second polyimide photoresist layer, such that the third metal layer extends into the hole in the crosslinked second polyimide photoresist layer to contact a corresponding one of the second conductive traces;
forming a second photoresist mask layer on the third metal layer;
patterning the second photoresist mask layer and the third metal layer using photolithography techniques so as to form a plurality of third conductive traces on the crosslinked second polyimide photoresist layer;
removing the patterned second photoresist mask layer from the third conductive traces; and
forming a third polyimide photoresist layer on the third conductive traces and areas of the crosslinked second polyimide photoresist layer that are exposed from the third conductive traces.

2. The method of claim 1, wherein the flexible substrate is made of polyimide.

3. The method of claim 1, wherein the first and second photoresist mask layers are made of a polyimide photoresist.

4. The method of claim 1, wherein the first metal layer is a metal foil laminated to the flexible substrate.

5. A method of making a flexible multilayer circuit board, comprising:
preparing an assembly of a flexible substrate and a first metal layer that is formed on a first surface of the flexible substrate, the first metal layer being patterned and having a plurality of first conductive traces;
forming a first polyimide photoresist layer on the first metal layer and areas of the first surface that are exposed from the first metal layer;
exposing the first polyimide photoresist layer to a light to permit the first polyimide photoresist layer to undergo crosslinking reaction;
forming a second metal layer on the crosslinked first polyimide photoresist layer;
forming a first photoresist mask layer of a polyimide photoresist on the second metal layer;
patterning the first photoresist mask layer and the second metal layer using photolithography techniques so as to form a plurality of second conductive traces on the crosslinked first polyimide photoresist layer and a plurality of pattern holes extending through the patterned second metal layer and the patterned first photoresist mask layer;
filling the pattern holes with a polyimide photoresist and exposing the polyimide photoresist in the pattern holes to a light to permit the polyimide photoresist in the pattern holes to undergo crosslinking reaction, so that the crosslinked polyimide photoresist in the pattern holes and the patterned first photoresist mask layer cooperatively define a second polyimide photoresist layer; and
forming at least one hole in the second polyimide photoresist layer, such that the at least one hole exposes an area of a corresponding one of the second conductive traces.

6. The method of claim 5, further comprising:
forming a third metal layer on the second polyimide photoresist layer, such that the third metal layer extends into the at least one hole in the second polyimide photoresist layer to contact a corresponding one of the second conductive traces;
forming a second photoresist mask layer of a polyimide photoresist on the third metal layer; and
patterning the second photoresist mask layer and the third metal layer using photolithography techniques so as to form a plurality of third conductive traces on the second polyimide photoresist layer and a plurality of pattern holes extending through the patterned third metal layer and the patterned second photoresist mask layer.

7. The method of claim 6, further comprising:
filling the pattern holes with a polyimide photoresist and exposing the polyimide photoresist in the pattern holes to a light to permit the polyimide photoresist in the pattern holes to undergo crosslinking reaction, so that the crosslinked polyimide photoresist in the pattern holes and the patterned second photoresist mask layer cooperatively define a third polyimide photoresist layer.

8. The method of claim 5, wherein formation of the at least one hole in the second polyimide photoresist layer is conducted by dry etching or laser drilling.
